(19) United States
(12) Patent Application Publication
(10) Pub. No.: US 2026/0298727 A1
(43) Pub. Date: Oct. 1, 2026

(54) ON-CHIP TEMPERATURE SENSOR

(71) Applicant: STMicroelectronics International N.V., Geneva (CH)

(72) Inventors: Anuj BHARDWAJ, New Delhi (IN); Kedar Janardan DHORI, Ghaziabad (IN); Anand Kumar MISHRA, Ghaziabad (IN)

(73) Assignee: STMicroelectronics International N.V., Geneva (CH)

(21) Appl. No.: 19/578,630

(22) Filed: Mar. 25, 2026

Related U.S. Application Data
(60) Provisional application No. 63/781,030, filed on Mar. 31, 2025.

(51) Int. Cl. G01K 7/00; H10W 40/50

(52) U.S. Cl. CPC G01K 7/00; G01K 2217/00; G01K 2219/00; H10W 40/50

(57) ABSTRACT

According to the present disclosure, a temperature sensor operates based on a principle of leakage variation with temperature, which follows an exponential trend. With an increase in temperature, the frequency of the sensor increases due to an increase in leakage current. The frequency is converted to a digital, binary code based on output of a counter, which provides a measure of a temperature of a semiconductor substrate. Data output by the temperature sensor can be used to perform adaptive voltage scaling (AVS) or adaptive body bias (ABB).

### BACKGROUND

### Technical Field

The present disclosure relates in general to temperature sensors, and in particular to temperature sensors that sense temperatures of semiconductor substrates.

### Description of the Related Art

Temperature sensing is a critical part of any chip, wherein temperature information can provide critical info about compensation needs. Conventional temperature sensors either require a proportional to absolute temperature (PTAT) current or voltage source which are then converted to digital values through analog-to-digital converters (ADCs).

Diode connected metal-oxide-semiconductor field-effect transistor (MOSFET) based temperature sensors are prone to inaccuracy owing to second order effects such as temperature inversion which do not allow them to work at low voltages. Moreover, diode connected MOSFTEs and bipolar junction transistors (BJTs) produce analog data which again require ADCs for post-processing.

Such conventional temperature sensors have many drawbacks including that they require a high area of a semiconductor substrate to implement, have high power consumption, and have integration complexities. In analog based sensors, routing requires shielding/isolation which is complex because it involves two wire routing. For example, if ADCs among various distributed sensors (only sensing elements) across a die were to be shared, two wires would have to be routed to the ADCs and both wires would require shielding/isolation which is complicated to handle in a digital on top flow.

### BRIEF SUMMARY

Owing to the above, the inventors of the present disclosure have found that an all-digital temperature sensor can be a possible solution to design a low area, low power temperature sensor. Embodiments of the present disclosure are directed to an on-chip temperature sensor that provides digital output. The sensors work on a principle of leakage variation with temperature which follows an exponential trend. With an increase in temperature, the frequency of the sensor increases due to an increase in leakage current. The frequency is converted to a binary code through a counter that provides a measure of a temperature of a semiconductor substrate.

A temperature sensor according to the present disclosure may be characterized as including: one or more sensing elements on a semiconductor substrate and a controller on the semiconductor substrate and coupled to the one or more sensing elements. The one or more sensing elements, in operation, output one or more output signals, respectively. The controller, in operation, predicts a temperature of the semiconductor substrate based on the one or more output signals output by the one or more sensing elements. The controller, in operation, outputs data based on the temperature of the semiconductor substrate. Each of the one or more sensing elements includes a plurality of sensing circuits electrically coupled in series, where each of the one or more sensing circuits includes: an input terminal; an output terminal; a first transistor having a first terminal electrically coupled to a supply potential, a second terminal electrically coupled to a first terminal of a second transistor, a third terminal of a fourth transistor, a third terminal of a fifth transistor, a third terminal of a sixth transistor, and a third terminal of a seventh transistor, and a third terminal electrically coupled to the input terminal; the second transistor having the first terminal electrically coupled to the second terminal of the first transistor, the third terminal of the fourth transistor, the third terminal of the fifth transistor, the third terminal of the sixth transistor, and the third terminal of the seventh transistor, a second terminal electrically coupled to the first terminal of a third transistor, and a third terminal electrically coupled to a ground potential; the third transistor having the first terminal electrically coupled to the second terminal of the second transistor, a second terminal electrically coupled to the ground potential, and a third terminal coupled to the input terminal; the fourth transistor having a first terminal electrically coupled to the supply potential, a second terminal electrically coupled to the first terminal of a fifth transistor and a first terminal an eighth transistor, and the third terminal electrically coupled to the second terminal of the first transistor and the first terminal of the second transistor; the fifth transistor having the first terminal electrically coupled to the second terminal of the fourth transistor and the first terminal of the eighth transistor, a second terminal electrically coupled to a first terminal of a sixth transistor and a first terminal of a nineth transistor, and the third terminal electrically coupled to the second terminal of the first transistor and the first terminal of the second transistor; the sixth transistor having the first terminal electrically coupled to the second terminal of the fifth transistor and the first terminal of the nineth transistor, a second terminal electrically coupled to a first terminal of a seventh transistor, a third terminal of the nineth transistor, and the output terminal, and the third terminal electrically coupled to the second terminal of the first transistor and the first terminal of the second transistor; the seventh transistor having the first terminal electrically coupled to the second terminal of the sixth transistor, a third terminal of the nineth transistor, and the output terminal, a second terminal electrically coupled to the ground potential, and the third terminal electrically coupled to the second terminal of the first transistor and the first terminal of the second transistor; the eighth transistor having the first terminal electrically coupled to the second terminal of the fourth transistor and the first terminal of the fifth transistor, a second terminal electrically coupled to the ground potential, and a third terminal electrically coupled to the second terminal of the sixth transistor, the first terminal of the seventh transistor, and the output terminal; and the nineth transistor having the first terminal electrically coupled to the second terminal of the fifth transistor and the first terminal of the sixth transistor, a second terminal electrically coupled to the ground potential, and the third terminal electrically coupled to the second terminal of the sixth transistor, the first terminal of the seventh transistor, the third terminal of the eighth transistor, and the output terminal.

The data output by the controller may indicate the temperature of the semiconductor substrate.

The data output by the controller, in operation, may cause a voltage supplied to the controller to change.

The data output by the controller, in operation, may causes a voltage supplied to a body of a transistor disposed on the semiconductor substrate to change.

Each of the one or more sensing elements may include an inverter electrically coupled in series with the sensing circuits.

Each of the one or more sensing elements may include a counter that, in operation, outputs one of the one or more output signals.

The second transistor may operate in leakage mode, and the controller, in operation, may predict the temperature of the semiconductor substrate based on one or more frequencies of the one or more output signals output by the one or more sensing elements.

A temperature sensor according to the present disclosure may be characterized as including: one or more sensing elements on a semiconductor substrate, and a controller on the semiconductor substrate and coupled to the one or more sensing elements. The one or more sensing elements, in operation, output one or more output signals, respectively. The controller, in operation, predicts a temperature of the semiconductor substrate based on the one or more output signals output by the one or more sensing elements. The controller, in operation, outputs data based on the temperature of the semiconductor substrate. Each of the one or more sensing elements includes a plurality of sensing circuits electrically coupled in series. Each of the one or more sensing circuits includes: an input terminal; an output terminal; a first transistor having a first terminal electrically coupled to a supply potential, a second terminal electrically coupled to a first terminal of a second transistor, a third terminal of a fourth transistor, a third terminal of a fifth transistor, and a third terminal of a sixth transistor, and a third terminal electrically coupled to the input terminal; the second transistor having the first terminal electrically coupled to the second terminal of the first transistor, the third terminal of the fourth transistor, the third terminal of the fifth transistor, and the third terminal of the sixth transistor, a second terminal electrically coupled to a first terminal of a third transistor, and a third terminal electrically coupled to a ground potential; the third transistor having the first terminal electrically coupled to the second terminal of the second transistor, a second terminal electrically coupled to the ground potential, and a third terminal coupled to the input terminal; the fourth transistor having a first terminal electrically coupled to the supply potential, a second terminal electrically coupled to a first terminal of a fifth transistor and a first terminal of a seventh transistor, and the third terminal electrically coupled to the second terminal of the first transistor and the first terminal of the second transistor; the fifth transistor having the first terminal electrically coupled to the second terminal of the fourth transistor and the first terminal of the seventh transistor, a second terminal electrically coupled to a first terminal of a sixth transistor, a third terminal of a seventh transistor, and the output terminal, and the third terminal electrically coupled to the second terminal of the first transistor and the first terminal of the second transistor; the sixth transistor having the first terminal electrically coupled to the second terminal of the fifth transistor, the third terminal of the seventh transistor, and the output terminal, a second terminal electrically coupled to the ground potential, and a third terminal electrically coupled to the second terminal of the first transistor and the first terminal of the second transistor; and the seventh transistor having a first terminal electrically coupled to the second terminal of the fourth transistor and the first terminal of the fifth transistor, a second terminal electrically coupled to the ground potential, and the third terminal electrically coupled to the second terminal of the fifth transistor, the first terminal of the sixth transistor, and the output terminal.

The data output by the controller may indicate the temperature of the semiconductor substrate.

The data output by the controller, in operation, may cause a voltage supplied to the controller to change.

The data output by the controller, in operation, may cause a voltage supplied to a body of a transistor disposed on the semiconductor substrate to change.

Each of the one or more sensing elements may include an inverter electrically coupled in series with the sensing circuits.

Each of the one or more sensing elements may include a counter that, in operation, outputs one of the one or more output signals.

The second transistor may operate in leakage mode, and the controller, in operation, may predict the temperature of the semiconductor substrate based on one or more frequencies of the one or more output signals output by the one or more sensing elements.

A method of operating a temperature sensor on a semiconductor substrate according to the present disclosure may be characterized as including: receiving a first output signal from a sensing element of the temperature sensor; measuring a frequency of the first output signal; obtaining a plurality of coefficient values of a quadratic equation based on the frequency of the first output signal; and storing the coefficient value in a memory of a controller of the temperature sensor for process centering correction.

The method may further include receiving a second output signal at the controller of the temperature sensor from the sensing element of the temperature sensor; obtaining data based on a frequency of the second output signal and the coefficient values stored in the memory of the controller; and outputting the data. The method may further include obtaining evaluation data by modeling, based on the quadratic equation, a plurality of frequency values of the second output signal respectively corresponding to a plurality of temperature values of the semiconductor substrate, where the data indicates a temperature of the semiconductor substrate, and where the temperature of the semiconductor substrate is obtained based on the evaluation data. The quadratic equation may be y=A*exp(−((x−B)/C)\hat{ }2), where y is the frequency of the second output signal and A, B, and C are the coefficient values. The data may indicate a temperature of the semiconductor substrate. The method may further include causing a voltage supplied to the controller to change based on the data. The method may further include causing a voltage supplied to a body of a transistor disposed on the semiconductor substrate to change based on the data. The method may further include measuring a frequency of the second output signal by counting a number of times the second output signal completes one cycle during a sampling window.

### BRIEF DESCRIPTION OF THE SEVERAL VIEWS OF THE DRAWINGS

Non-limiting and non-exhaustive embodiments are described with reference to the following drawings. In the drawings, like reference numerals refer to like parts throughout the various figures unless otherwise specified.

For a better understanding of the present disclosure, reference will be made to the following Detailed Description, which is to be read in association with the accompanying drawings:

FIG. 1A shows a block diagram of a temperature sensor according to an embodiment of the present disclosure, and FIG. 1B shows a block diagram of a sensing element according to an embodiment of the present disclosure.

FIG. 2A shows a block diagram of a sensing circuit according to a first embodiment of the present disclosure, and FIG. 2B shows a block diagram of a sensing circuit according to a second embodiment of the present disclosure.

FIG. 3 shows a flowchart of a method according to an embodiment of the present disclosure.

FIG. 4 shows a graph for explaining aspects of the present disclosure.

FIGS. 5A, 5B, and 5C show graphs for explaining aspects of the present disclosure.

### DETAILED DESCRIPTION

According to the present disclosure, a temperature sensor operates based on a principle of leakage variation with temperature, which follows an exponential trend. With an increase in temperature, the frequency of the sensor increases due to an increase in leakage current. The frequency is converted to a digital, binary code based on output of a counter, which provides a measure of a temperature of a semiconductor substrate.

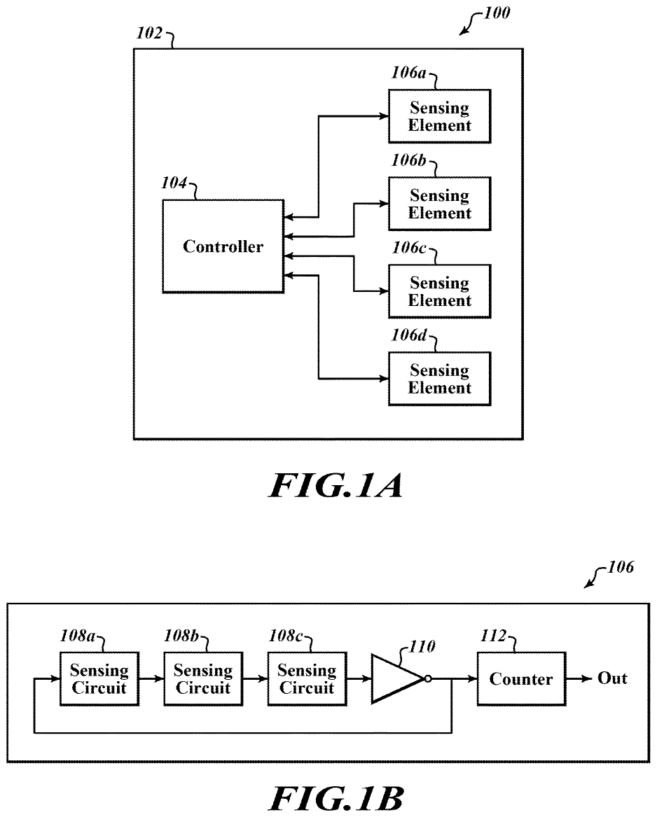

FIG. 1A shows a block diagram of a temperature sensor 100 according to an embodiment of the present disclosure. The temperature sensor 100 is formed on a semiconductor substrate 102. The substrate 102 may be made of silicon, for example. The present disclosure is not limited silicon substrates. Semiconductor substrates 102 formed from other materials are within the scope of the present disclosure.

The temperature sensor 100 includes a controller 104. In one or more implementations, the controller 104 includes a processor and a memory storing instructions that, when executed by the processor, cause the controller 104 to perform the acts described herein.

In addition, the temperature sensor 100 includes one or more sensing elements. In the embodiment shown in FIG. 1A, the temperature sensor 100 includes four sensing elements, including sensing element 106a, sensing element 106b, sensing element 106c, and sensing element 106d. Temperature sensors 100 that include fewer or more sensing elements are within the scope of the present disclosure.

FIG. 1B shows a block diagram of a sensing element 106 according to an embodiment of the present disclosure. Each of the sensing element 106a, sensing element 106b, sensing element 106c, and sensing element 106d shown in FIG. 1A has the same structure as the sensing element 106 shown in FIG. 1B.

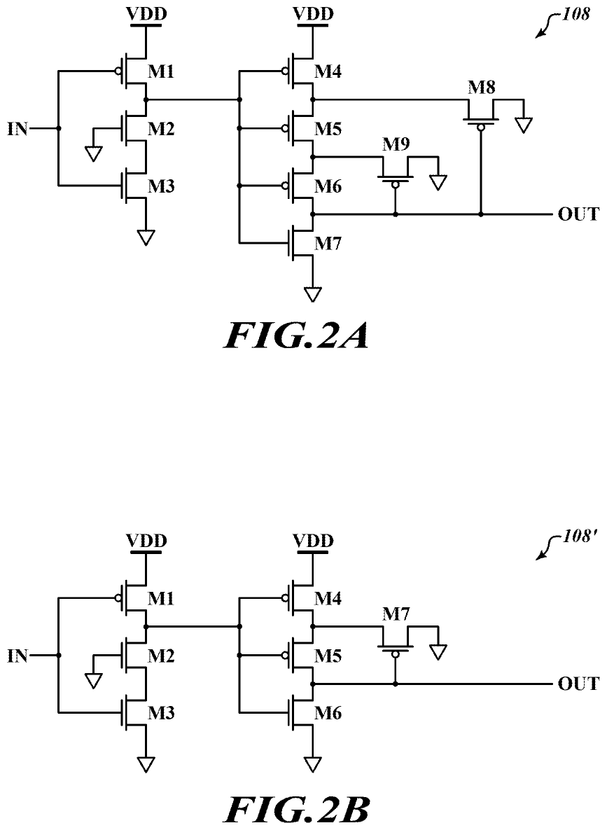

The sensing element 106 includes a plurality of sensing circuits, including sensing circuit 108a, sensing circuit 108b, and sensing circuit 108c, which will be described in greater detail with reference to FIGS. 2A and 2B. The sensing circuit 108a, sensing circuit 108b, and sensing circuit 108c are electrically connected in series with an inverter 110 and a counter 112. The sensing circuit 108a, sensing circuit 108b, sensing circuit 108c, and inverter 110 form a ring oscillator. The embodiment of the sensing element 106 shown in FIG. 1B includes three sensing circuits; however, the sensing element 106 may include a different number of sensing circuits without departing from the scope of the present disclosure, so long as the number of sensing circuits plus the number of inverters (i.e., 1) is greater than one and is an odd number (e.g., 3, 5, 7, 9, etc.).

The counter 112 shown in FIG. 1B communicates with the controller 104 shown in FIG. 1A. The controller 104 provides a signal indicating a sampling window to the counter 112.

In response, the counter 112 counts a number of times a signal input to the counter 112 completes one cycle during the sampling window, and outputs a signal indicating the number of times the signal input to the counter 112 completes one cycle during the sampling window, which is the frequency of the signal input to the counter 112. In one or more implementations, the counter 112 counts the number of times the signal input to the counter 112 completes one cycle during the sampling window by determining the number rising or falling edges of the signal input to the counter 112 during the sampling window.

FIG. 2A shows a block diagram of a sensing circuit 108 according to a first embodiment of the present disclosure. The sensing circuit 108 includes an input terminal IN, an output terminal OUT, and a plurality of transistors, including transistor M1, transistor M2, transistor M3, transistor M4, transistor M5, transistor M6, transistor M7, transistor M8, and transistor M9. The transistors M4-M7 form a stack. In the embodiment shown in FIG. 2A the sensing circuit 108 includes a stack with four transistors.

In some embodiments, a sensing circuit includes a stack with more than four transistors, which can improve the sensitivity of the sensing circuit. For example, instead of the transistor M7 being a N-type MOS transistor, the transistor M7 is a P-type MOS transistor, and instead of the second terminal of the transistor M7 being electrically coupled to the ground potential as shown in FIG. 2A, the second terminal of the transistor M7 is electrically coupled to a first terminal (e.g., source terminal) of a tenth transistor (not shown in FIG. 2A), which is a N-type MOS transistor having a second terminal (e.g., drain terminal) electrically coupled to the ground potential, and a third terminal (e.g., gate terminal) electrically coupled to the second terminal of the transistor M1, the first terminal of the transistor M2, and the third terminals of the transistors M4-M7. In addition, the sensing circuit includes an eleventh transistor (not shown in FIG. 2A) that is a P-type MOS transistor having a first terminal (e.g., source terminal) electrically coupled to the second terminal of the transistor M7 and the first terminal of the tenth transistor, a second terminal (e.g., drain terminal) electrically coupled to the ground potential, and a third terminal (e.g., gate terminal) electrically coupled to the output terminal OUT and the third terminals of the transistors M8 and M9.

In the sensing circuit 108 shown in FIG. 2A, the transistor M1 is a positive-type MOSFET (P-type MOS) transistor. The transistor M1 has a first terminal (e.g., source terminal) electrically coupled to a supply potential VDD (e.g., 5 Volts), a second terminal (e.g., drain terminal) electrically coupled to a first terminal of the transistor M2, a third terminal of a transistor M4, a third terminal of a transistor M5, a third terminal of a transistor M6, and a third terminal of a transistor M7, and a third terminal (e.g., gate terminal) electrically coupled to the input terminal IN.

In the sensing circuit 108 shown in FIG. 2A, the transistor M2 is an enhancement mode negative-type MOSFET (N-type MOS) transistor, which is always off. The transistor M2 has the first terminal (e.g., source terminal) electrically coupled to the second terminal of the transistor M1, the third terminal of the transistor M4, the third terminal of the transistor M5, the third terminal of the transistor M6, and the third terminal of a transistor M7, a second terminal (e.g., drain terminal) electrically coupled to a first terminal of the transistor M3, and a third terminal (e.g., gate terminal) electrically coupled to a ground potential (e.g., 0 Volts).

In the sensing circuit 108 shown in FIG. 2A, the transistor M3 is an N-type MOS transistor. The transistor M3 has a first terminal (e.g., source terminal) electrically coupled to the second terminal of the transistor M2, a second terminal (e.g., drain terminal) electrically coupled to the ground potential, and a third terminal (e.g., gate terminal) coupled to the input terminal IN.

In the sensing circuit 108 shown in FIG. 2A, the transistor M4 is a P-type MOS transistor. The transistor M4 has a first terminal (e.g., source terminal) electrically coupled to the supply potential VDD, a second terminal (e.g., drain terminal) electrically coupled to a first terminal of the transistor M5 and a first terminal of the transistor M8, and a third terminal (e.g., gate terminal) electrically coupled to the second terminal of the transistor M1 and the first terminal of the transistor M2.

In the sensing circuit 108 shown in FIG. 2A, the transistor M5 is a P-type MOS transistor. The transistor M5 has the first terminal (e.g., source terminal) electrically coupled to the second terminal of the transistor M4 and the first terminal of the transistor M8, a second terminal (e.g., drain terminal) electrically coupled to a first terminal of the transistor M6 and a first terminal of the transistor M9, and the third terminal (e.g., gate terminal) electrically coupled to the second terminal of the transistor M1 and the first terminal of the transistor M2.

In the sensing circuit 108 shown in FIG. 2A, the transistor M6 is a P-type MOS transistor. The transistor M6 has a first terminal (e.g., source terminal) electrically coupled to the second terminal of the transistor M5 and a first terminal of the transistor M9, a second terminal (e.g., drain terminal) electrically coupled to a first terminal of the transistor M7, a third terminal of the transistor M8, a third terminal of the transistor M9, and the output terminal OUT, and the third terminal (e.g., gate terminal) electrically coupled to the second terminal of the transistor M1 and the first terminal of the transistor M2.

In the sensing circuit 108 shown in FIG. 2A, the transistor M7 is an N-type MOS transistor. The transistor M7 has the first terminal (e.g., source terminal) electrically coupled to the second terminal of the transistor M6, the third terminal of the transistor M8, the third terminal of the transistor M9, and the output terminal OUT, a second terminal (e.g., drain terminal) electrically coupled to the ground potential, and the third terminal electrically coupled to the second terminal of the transistor M1 and the first terminal of the transistor M2.

In the illustrated embodiment, the transistor M8 is a P-type MOS transistor. The transistor M8 has the first terminal (e.g., source terminal) electrically coupled to the second terminal of the transistor M4 and the first terminal of the transistor M5, a second terminal (e.g., drain terminal) electrically coupled to the ground potential, and the third terminal electrically coupled to the second terminal of the transistor M6, the first terminal of the transistor M7, the third terminal of the transistor M9, and the output terminal OUT.

In the sensing circuit 108 shown in FIG. 2A, the transistor M9 is a P-type MOS transistor. The transistor M9 has the first terminal (e.g., source terminal) electrically coupled to the second terminal of the transistor M5 and the first terminal of the transistor M6, a second terminal (e.g., drain terminal) electrically coupled to the ground potential, and the third terminal electrically coupled to the second terminal of the transistor M6, the first terminal of the transistor M7, the third terminal of the transistor M8, and the output terminal OUT.

Having described the structure of the sensing circuit 108 shown in FIG. 2A, operation of the sensing circuit 108 will now be described. When a voltage at the input terminal IN is low (e.g., 0 Volts, “0”), the transistor M1 turns ON, the transistor M2 is OFF, the transistor M3 is OFF, the transistor M1 drives a node coupled to the second terminal of the transistor M1, to the supply potential VDD very quickly, and the transistors M4-M6 are OFF, which turns the transistor M7 ON and causes a voltage at the output terminal OUT to low (e.g., 0 Volts, “0”). When the voltage at the input terminal IN transitions from low to high (e.g., 5 Volts, “1”), the transistor M3 turns ON with the transistor M2 still OFF and operating in leakage mode, and the transistor M1 is OFF and the voltage at an intermediate node coupled to the second terminal of the transistor M1, the first terminal of the transistor M2, and the third terminals of the transistors M4-M7 charges slowly, which causes the voltage at the output terminal OUT to go high (e.g., 5 Volts, “1”). When temperature increases, the frequency of a signal output by the output terminal OUT increases.

The transistors M4-M9 increase temperature dependence on the transistor M2. When the voltage at the output terminal OUT is low (e.g., 0 Volts, “0”), the transistors M8 and M9 turn ON. When an intermediate voltage between the transistors M4 and M5 discharges to a sufficiently low level that causes the voltage at the output terminal OUT to toggle and become low, the transistors M8 and M9 turn ON and the intermediate voltage between the transistors M4 and M5, and an intermediate voltage between the transistors M5 and M6 become the supply voltage VDD minus a threshold voltage V_{threshold} of the transistors M8 and M9, respectively, which remove other dependencies of the transistors M4-M7 from the sensing circuit 108.

When an intermediate voltage between the transistors M1 and M2 is one-half of the supply voltage VDD, for example, the transistors M4-M7 remain OFF. With the sensing circuit 108, there is a one-to-one correspondence between the frequency of the signal at the output terminal OUT and the temperature of the semiconductor substrate 102.

FIG. 2B shows a block diagram of a sensing circuit 108′ according to a second embodiment of the present disclosure. The sensing circuit 108′ includes an input terminal IN, an output terminal OUT, and a plurality of transistors, including a transistor M1, a transistor M2, a transistor M3, a transistor M4, a transistor M5, a transistor M6, and a transistor M7.

In the sensing circuit 108′ shown in FIG. 2B, the transistor M1 is a P-type MOS transistor. The transistor M1 has a first terminal (e.g., source terminal) electrically coupled to a supply potential VDD (e.g., 5 Volts), a second terminal (e.g., drain terminal) electrically coupled to a first terminal of the transistor M2, and a third terminal (e.g., gate terminal) electrically coupled to the input terminal IN.

In the sensing circuit 108′ shown in FIG. 2B, the transistor M2 is an enhancement mode N-type MOS transistor. The transistor M2 has a first terminal (e.g., source terminal) electrically coupled to the second terminal of the transistor M1, a second terminal (e.g., drain terminal) electrically coupled to a first terminal of the transistor M3, and a third terminal (e.g., gate terminal) electrically coupled to a ground potential (e.g., 0 Volts).

In the sensing circuit 108′ shown in FIG. 2B, the transistor M3 is an N-type MOS transistor. The transistor M3 has a first terminal (e.g., source terminal) electrically coupled to the second terminal of the transistor M2, a second terminal (e.g., drain terminal) electrically coupled to the ground potential, and a third terminal (e.g., gate terminal) coupled to the input terminal IN.

In the sensing circuit 108′ shown in FIG. 2B, the transistor M4 is a P-type MOS transistor. The transistor M4 has a first terminal (e.g., source terminal) electrically coupled to the supply potential VDD, a second terminal (e.g., drain terminal) electrically coupled to a first terminal of the transistor M5 and a first terminal of the transistor M7, and a third terminal (e.g., gate terminal) electrically coupled to the second terminal of the transistor M1 and the first terminal of the transistor M2.

In the sensing circuit 108′ shown in FIG. 2B, the transistor M5 is a P-type MOS transistor. The transistor M5 has a first terminal (e.g., source terminal) electrically coupled to the second terminal of the transistor M4, a second terminal (e.g., drain terminal) electrically coupled to a first terminal of the transistor M6, a second terminal of the transistor M7, and the output terminal OUT, and a third terminal (e.g., gate terminal) electrically coupled to the second terminal of the transistor M1 and the first terminal of the transistor M2.

In the sensing circuit 108′ shown in FIG. 2B, the transistor M6 is an N-type MOS transistor. The transistor M6 has a first terminal (e.g., source terminal) electrically coupled to the second terminal of the transistor M5, a second terminal (e.g., drain terminal) electrically coupled to the ground potential, and a third terminal (e.g., gate terminal) electrically coupled to the second terminal of the transistor M1 and the first terminal of the transistor M2.

In the sensing circuit 108′ shown in FIG. 2B, the transistor M7 is a P-type MOS transistor. The transistor M7 has a first terminal (e.g., source terminal) electrically coupled to the second terminal of the transistor M4 and the first terminal of the transistor M5, a second terminal (e.g., drain terminal) electrically coupled to the ground potential, and a third terminal (e.g., gate terminal) electrically coupled to the second terminal of the transistor M5, the first terminal of the transistor M6, and the output terminal OUT. Operation of the sensing circuit 108′ is similar in many relevant respects to operation of the sensing circuit 108 described above.

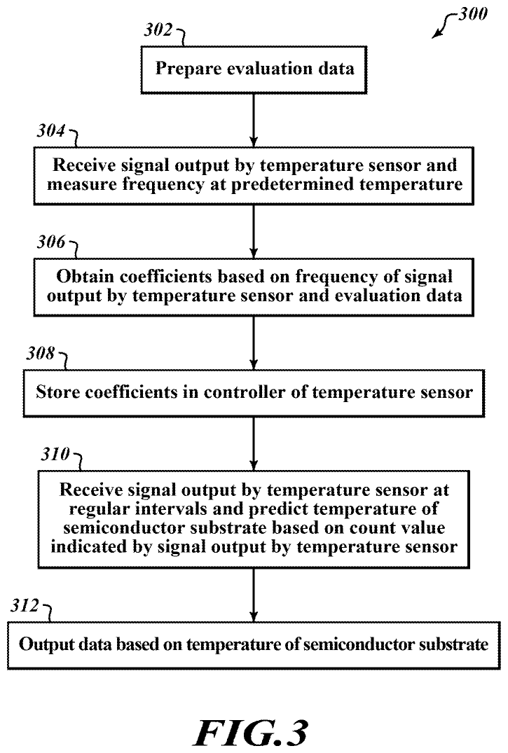

FIG. 3 shows a flowchart of a method 300 according to an embodiment of the present disclosure. The method 300 begins at 302.

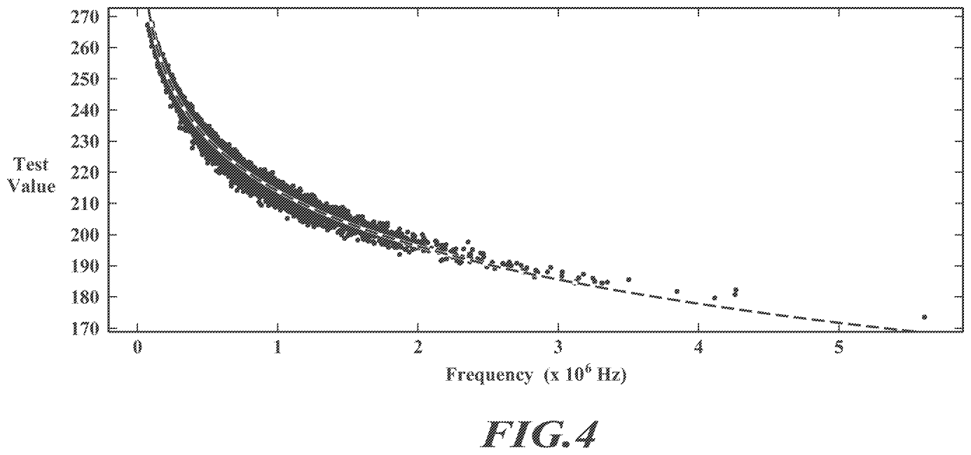

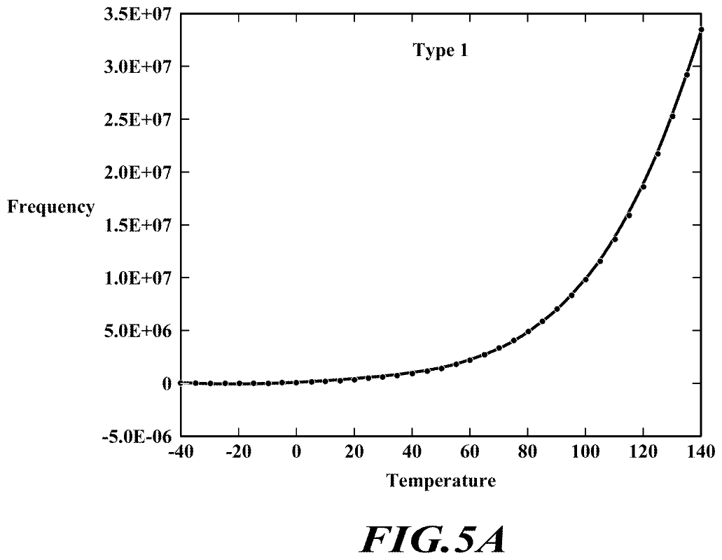

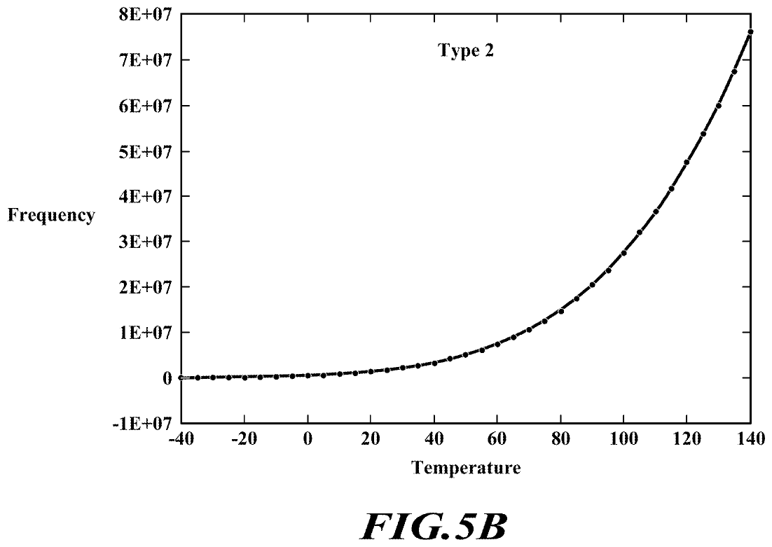

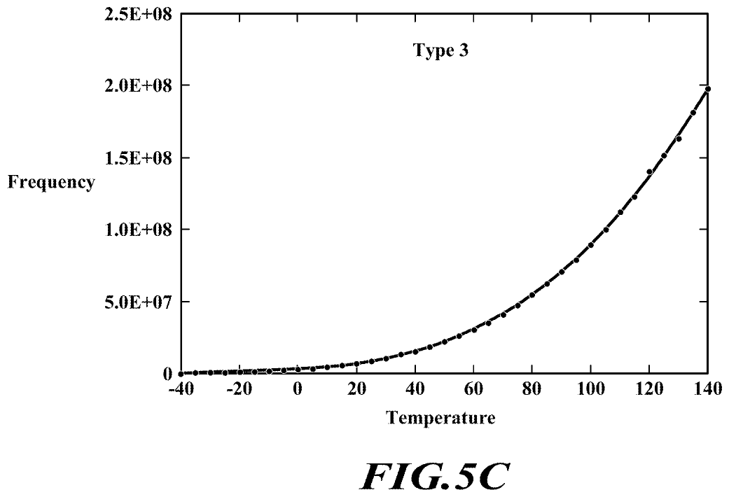

At 302, evaluation data is prepared. For example, the evaluation data is prepared by a computer (not shown). Generation of the evaluation data will be described below with reference to FIGS. 4, 5A, 5B, and 5C. The method 300 then proceeds to 304.

At 304, at a predetermined temperature (e.g., 25° C.), a signal output by a temperature sensor (e.g., temperature sensor 100) is received by a test device (a computer, not illustrated), and the test device measures a frequency of the signal output by the temperature sensor. The method 300 then proceeds to 306.

At 306, the test device obtains coefficients of an equation (e.g., a quadratic equation) based on the frequency of the signal output by sensor that is measured at 304 and the evaluation data generated at 302. For example, the test device uses data corresponding to the graph shown in FIG. 4 to obtain a corresponding test value, and then uses the test value to obtain the corresponding coefficient values. The coefficient values may be used for process centering correction. The method 300 then proceeds to 308.

At 308, the test device stores the coefficients obtained at 306 in a memory of a controller (e.g., controller 104) of the temperature sensor. For example, the test device stores the coefficients obtained at 306 in a non-volatile memory of the temperature sensor so that the temperature sensor can use the coefficients after the temperature sensor is powered OFF and ON. The method 300 then proceeds to 310.

In one implementation, 302-308 described above are performed at a manufacturing facility of a manufacturer of the temperature sensor before the temperature sensor has been purchased. Also, 310-312 described below are performed during use of the temperature sensor, for example, after the temperature sensor has been purchased.

At 310, the controller of the temperature sensor receives a signal output by at least one sensing element (e.g., sensing elements 106a-106d) and predicts a temperature of a semiconductor substrate (e.g., semiconductor substrate 102) based on a count value indicated by the signal output by at least one sensing element (e.g., counted by the counter 112). For example, the controller of the temperature sensor stores an equation corresponding to FIG. 5A (y=0.0791x⁴+11.275x³+553.89x²+23759x+545981R²=1) and solves the equation for x, which is the temperature. The method 300 then proceeds to 312.

At 312, the controller of the temperature sensor outputs data based on the temperature of the semiconductor substrate based on the temperature measured at 310. For example, the data output by the temperature sensor at 312 includes a binary code or digital value corresponding to the temperature of the semiconductor substrate. By way of another example, the data output by the temperature sensor at 312 includes a command configured to cause a voltage supplied to the controller to change, to implement adaptive voltage scaling (AVS). By way of yet another example, the data output by the temperature sensor at 312 includes a command configured to cause a voltage supplied to a body of a transistor disposed on the semiconductor substrate to change, to implement adaptive body bias (ABB). The method 300 then ends.

FIG. 4 shows a graph for explaining aspects of the present disclosure. The graph shows a coefficient versus frequency curve at a predetermined temperature (e.g., 25° C.), The graph includes a plurality of test values respectively associated with a plurality of frequency values. In one or more implementations, the graph shown in FIG. 4 is generated based on the quadratic equation y=A*exp(−((x−B)/C)\hat{ }2), which models the relationship between observed frequency and temperature of a semiconductor substrate, where A=a1*x\hat{ }b1, B=a1*x\hat{ }b1+c1, and C=a1*x\hat{ }b1, using a plurality of different frequency values (e.g., from 0 to 6*10⁶) and a plurality of different values of the coefficients A, B, and C, which depend on a type of the semiconductor substrate. For example, at 306 shown in FIG. 3, the test device uses the frequency of the signal output by the temperature sensor measured at the predetermined temperature at 307, to predict the coefficients A, B, and C through their respective equations which are power laws using the equations above.

FIGS. 5A, 5B, and 5C show graphs for explaining aspects of the present disclosure. Each of the graphs shown in FIGS. 5A, 5B, and 5C includes a plurality of frequency values respectively associated with a plurality of temperature values, for different types of semiconductor substrates. Each of the graphs shown in 5A, 5B, and 5C is a leakage current frequency versus temperature curve.

The graph shown in FIG. 5A is for a type of semiconductor substrate formed based on a process corner corresponding to a Typical-Typical (TT) variation of fabrication parameters used in applying an integrated circuit design to a semiconductor wafer. In one embodiment, the graph shown in FIG. 5A is generated based on an equation of y=0.0883x⁴−2.1403x³+167.22x²+13841x+101195R².

The graph shown in FIG. 5B is for a type of semiconductor substrate formed based on a process corner corresponding to a Slow-Slow (SS) variation of fabrication parameters used in applying an integrated circuit design to a semiconductor wafer. In one embodiment, the graph shown in FIG. 5B is generated based on an equation of y=0.0791x⁴+11.275x³+553.89x²+23759x+545981R².

The graph shown in FIG. 5B is for a type of semiconductor substrate formed based on a process corner corresponding to a Fast-Fast (FF) variation of fabrication parameters used in applying an integrated circuit design to a semiconductor wafer. In one embodiment, the graph shown in FIG. 5C is generated based on an equation of y=0.0445x⁴+50.869x³+2869.3x²+115944x+3000000R².

In one implementation, the controller 104 of the temperature sensor 100 shown in FIG. 1A stores data corresponding to the one of the equations described above for FIGS. 5A, 5B, and 5C. Accordingly, the temperature sensor 100 is able to more accurately predict the temperature of the substrate 102 taking into account process variations.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A temperature sensor, comprising:
one or more sensing elements on a semiconductor substrate; and
a controller on the semiconductor substrate and coupled to the one or more sensing elements,
wherein the one or more sensing elements, in operation, output one or more output signals, respectively,
wherein the controller, in operation, predicts a temperature of the semiconductor substrate based on the one or more output signals output by the one or more sensing elements,
wherein the controller, in operation, outputs data based on the temperature of the semiconductor substrate,
wherein each of the one or more sensing elements includes a plurality of sensing circuits electrically coupled in series, and
wherein each of the one or more sensing circuits includes:
an input terminal;
an output terminal;
a first transistor having a first terminal electrically coupled to a supply potential, a second terminal, and a third terminal electrically coupled to the input terminal;
a second transistor having a first terminal electrically coupled to the second terminal of the first transistor, a second terminal, and a third terminal electrically coupled to a ground potential;
a third transistor having a first terminal electrically coupled to the second terminal of the second transistor, a second terminal electrically coupled to the ground potential, and a third terminal coupled to the input terminal;
a fourth transistor having a first terminal electrically coupled to the supply potential, a second terminal, and a third terminal electrically coupled to the second terminal of the first transistor and the first terminal of the second transistor;
a fifth transistor having a first terminal electrically coupled to the second terminal of the fourth transistor, a second terminal, and a third terminal electrically coupled to the second terminal of the first transistor and the first terminal of the second transistor;
a sixth transistor having a first terminal electrically coupled to the second terminal of the fifth transistor, a second terminal electrically coupled to the output terminal, and a third terminal electrically coupled to the second terminal of the first transistor and the first terminal of the second transistor;
a seventh transistor having a first terminal electrically coupled to the second terminal of the sixth transistor and the output terminal, a second terminal electrically coupled to the ground potential, and a third terminal electrically coupled to the second terminal of the first transistor and the first terminal of the second transistor;
an eighth transistor having a first terminal electrically coupled to the second terminal of the fourth transistor and the first terminal of the fifth transistor, a second terminal electrically coupled to the ground potential, and a third terminal electrically coupled to the second terminal of the sixth transistor, the first terminal of the seventh transistor, and the output terminal; and
a nineth transistor having a first terminal electrically coupled to the second terminal of the fifth transistor and the first terminal of the sixth transistor, a second terminal electrically coupled to the ground potential, and a third terminal electrically coupled to the second terminal of the sixth transistor, the first terminal of the seventh transistor, and the output terminal.

2. The temperature sensor according to claim 1, wherein the data output by the controller indicates the temperature of the semiconductor substrate.

3. The temperature sensor according to claim 1, wherein the data output by the controller, in operation, causes a voltage supplied to the controller to change.

4. The temperature sensor according to claim 1, wherein the data output by the controller, in operation, causes a voltage supplied to a body of a transistor disposed on the semiconductor substrate to change.

5. The temperature sensor according to claim 1, wherein each of the one or more sensing elements includes an inverter electrically coupled in series with the sensing circuits.

6. The temperature sensor according to claim 1, wherein each of the one or more sensing elements includes a counter that, in operation, outputs one of the one or more output signals.

7. The temperature sensor according to claim 1, wherein the second transistor operates in leakage mode, and wherein the controller, in operation, predicts the temperature of the semiconductor substrate based on one or more frequencies of the one or more output signals output by the one or more sensing elements.

8. A temperature sensor, comprising:
one or more sensing elements on a semiconductor substrate; and
a controller on the semiconductor substrate and coupled to the one or more sensing elements,
wherein the one or more sensing elements, in operation, output one or more output signals, respectively,
wherein the controller, in operation, predicts a temperature of the semiconductor substrate based on the one or more output signals output by the one or more sensing elements,
wherein the controller, in operation, outputs data based on the temperature of the semiconductor substrate,
wherein each of the one or more sensing elements includes a plurality of sensing circuits electrically coupled in series, and
wherein each of the one or more sensing circuits includes:
an input terminal;
an output terminal;
a first transistor having a first terminal electrically coupled to a supply potential, a second terminal, and a third terminal electrically coupled to the input terminal;
a second transistor having a first terminal electrically coupled to the second terminal of the first transistor, a second terminal, and a third terminal electrically coupled to a ground potential;
a third transistor having a first terminal electrically coupled to the second terminal of the second transistor, a second terminal electrically coupled to the ground potential, and a third terminal coupled to the input terminal;
a fourth transistor having a first terminal electrically coupled to the supply potential, a second terminal, and a third terminal electrically coupled to the second terminal of the first transistor and the first terminal of the second transistor;
a fifth transistor having a first terminal electrically coupled to the second terminal of the fourth transistor, a second terminal, and a third terminal electrically coupled to the second terminal of the first transistor and the first terminal of the second transistor;
a sixth transistor having a first terminal electrically coupled to the second terminal of the fifth transistor, a second terminal electrically coupled to the ground potential, and a third terminal electrically coupled to the second terminal of the first transistor and the first terminal of the second transistor; and
an seventh transistor having a first terminal electrically coupled to the second terminal of the fourth transistor and the first terminal of the fifth transistor, a second terminal electrically coupled to the ground potential, and a third terminal electrically coupled to the second terminal of the fifth transistor, the first terminal of the sixth transistor, and the output terminal.

9. The temperature sensor according to claim 8, wherein the data output by the controller indicates the temperature of the semiconductor substrate.

10. The temperature sensor according to claim 8, wherein the data output by the controller, in operation, causes:
a voltage supplied to the controller to change; and/or
a voltage supplied to a body of a transistor disposed on the semiconductor substrate to change.

11. (canceled)

12. The temperature sensor according to claim 8, wherein each of the one or more sensing elements includes:
an inverter electrically coupled in series with the sensing circuits: and/or
a counter that, in operation, outputs one of the one or more output signals.

13. (canceled)

14. The temperature sensor according to claim 8, wherein the second transistor operates in leakage mode, and wherein the controller, in operation, predicts the temperature of the semiconductor substrate based on one or more frequencies of the one or more output signals output by the one or more sensing elements.

15. A method of operating a temperature sensor on a semiconductor substrate, comprising:
receiving a first output signal from a sensing element of the temperature sensor;
measuring a frequency of the first output signal;
obtaining a plurality of coefficient values of a quadratic equation based on the frequency of the first output signal; and
storing the coefficient values in a memory of a controller of the temperature sensor for process centering correction.

16. The method according to claim 15, further comprising:
receiving a second output signal at the controller of the temperature sensor from the sensing element of the temperature sensor;
obtaining data based on a frequency of the second output signal and the coefficient values stored in the memory of the controller; and
outputting the data.

17. The method according to claim 16, further comprising:
obtaining evaluation data by modeling, based on the quadratic equation, a plurality of frequency values of the second output signal respectively corresponding to a plurality of temperature values of the semiconductor substrate,
wherein the data indicates a temperature of the semiconductor substrate, and
wherein the temperature of the semiconductor substrate is obtained based on the evaluation data.

18. The method according to claim 17, wherein the quadratic equation is y=A*exp(−((x−B)/C)\hat{ }2), and wherein y is the frequency of the second output signal and A, B, and C are the coefficient values.

19. The method according to claim 16, wherein the data indicates a temperature of the semiconductor substrate.

20. The method according to claim 16, further comprising:
causing a voltage supplied to the controller to change based on the data.

21. The method according to claim 16, further comprising:
causing a voltage supplied to a body of a transistor disposed on the semiconductor substrate to change based on the data.

22. The method according to claim 16, further comprising:
measuring a frequency of the second output signal by counting a number of times the second output signal completes one cycle during a sampling window.
